(19) United States
(12) Patent Application Publication
(10) Pub. No.: US 2016/0246176 A1
(43) Pub. Date: Aug. 25, 2016

(54) Fabrication of Tetherable Patterned Thin Film with 3D Rolled-up Structure

(71) Applicant: National Tsing Hua University, Hsin Chu City (TW)

(72) Inventors: Zung-Hang Wei, Hsin Chu City (TW); Chen-Yu Huang, Hsin Chu City (TW); Tzong-Rong Ger, Hsin Chu City (TW)

(21) Appl. No.: 14/753,028

(22) Filed: Jun. 29, 2015

(30) Foreign Application Priority Data
Feb. 24, 2015 (TW) 104105887

(51) Int. Cl. G03F 7/16; G03F 7/38; G03F 7/40

(52) U.S. Cl. CPC G03F 7/16; G03F 7/40; G03F 7/38

(57) ABSTRACT

The present invention provides a fabrication of a tetherable patterned thin film with 3D tube-shaped structure. The fabrication includes following steps: preparing a substrate; covering a supportive layer onto the substrate; defining a pattern portion onto the supportive layer; depositing a thin film layer onto the pattern portion; opening at least one concavity onto the supportive layer; removing the substrate in a temperature range; and forming a tube-shaped thin film.

### CROSS-REFERENCE TO RELATED APPLICATIONS

This application claim priority to TAIWAN application Numbered 104105887, filed Feb. 24, 2015, which is herein incorporated by reference in its' integrity.

### TECHNICAL FIELD

The present invention generally relates to a fabrication of patterned thin film, and more particularly, to a fabrication of patterned thin film with tetherable 3D rolled-up structure.

### BACKGROUND OF RELATED ART

In microelectromechanical system, micromachining of silicon includes surface micromachining and bulk micromachining. Surface micromachining builds microstructures by depositing and etching different structural layers on top of the substrate. Bulk micromachining builds a silicon substrate selectively etched to produce structures. Each of two micromachining system above has its benefit and disadvantage, respectively. For example, in surface micromachining, due to the fabrication process involved series of 2D thin films stacking, which limit its modification. The control of thickness of the thin film and the techniques involved multiple mask process and sacrificial layers make the process of surface micromachining too complex. Thus, the utility of surface micromachining is restricted to planar configurations due to the difficulty in constructing structures in the direction perpendicular to the substrate. On the contrary, in bulk micromachining, the etched area and un-etched area form specific angle due to the diamond like lattice structure of silicon, which make it difficult to create micro structure with particular shape, in other words, the flexibility of design is limited.

In prior art, it has developed three-dimensional (3D) tubular structure with multilayered thin film structures due to strain-induced self-rolled-up, that includes planar layer which is formed by a sacrificial layer and one or more strained layer.

It is well-established that mismatch strains between different layers in thin film systems can induce mechanical deformation either in the form of surface waviness formation or in the form of bending and rolling of thin membranes.

Deposition method includes plasma-enhanced chemical vapor deposition (PECVD), metal-organic vapor deposition (MOCVD) and molecular beam epitaxy (MBE).

The material of thin film layer includes, epitaxial single crystal, amorphous polymers, metal or composite materials.

The sacrificial layer includes lattice-matched heterojunction generated from epitaxy, spun-on layers or semiconductor substrate.

Defining patterns on the surface can usually be achieved by lithography. Lithographic technique includes extreme ultraviolet lithography (EUV), X-ray lithography, electron projection lithography (EPL), ion projection lithography (IPL), electron-beam lithography (often abbreviated as e-beam lithography) and the like.

Recently, scientists have developed microelectromechanical system and/or an apparatus for cell culture in vitro and detection.

However, most biomedical devices are formed by 2D system. To integrate 2D material with normal physical property into 3D system, it must construct 3D supportive structure firstly on the substrate, and followed by covering a 2D material onto the 3D substrate, and therefore, it is complicated and difficult.

In order to solve the problem of the conventional arts, there is a need to provide simple fabrication process for preparing sensitive device based on 3D system. The present invention can not only maintain the physical property of the 2D patterned thin film material, but also improves detection by integrating 3D structure.

In addition, the present invention also provides a tetherable patterned thin film with 3D rolled-up structure to actively trap and detect the target objects.

### SUMMARY

An object of the present invention is to provide a patterned thin film with tube-shaped structure by strain-induced self-rolled-up technique. The present invention can improve biomedical technique and/or apparatus by combining 2D patterned thin film and tetherable 3D structure.

The present invention is to provide a method for preparing a patterned thin film with 3D hollow tubular structure. Due to the difference in thermal expansion coefficient between different layer, the 2D thin film can curve and scroll into a 3D tubular structure by etching the substrate to free from adhesion.

According to one embodiment, the present invention provides a fabrication of patterned thin film with tethered 3D rolled-up structure. The fabrication includes at least one substrate for allowing steps: covering a supportive layer onto the substrate; defining a pattern portion onto the supportive layer; depositing a thin film layer onto the pattern portion; opening three concavities onto supportive layer; and removing the substrate. The 2D thin film will bend or curl towards the layer (supportive layer or thin film layer) with higher coefficient of thermal expansion and form 3D tube-shaped structure.

According to one embodiment, the present invention provides a fabrication of patterned thin film with untethered 3D rolled-up structure. The fabrication includes allowing steps: preparing a substrate, covering a supportive layer onto the substrate; defining a pattern portion onto the supportive layer; depositing a thin film layer onto the pattern portion; opening four concavities onto supportive layer; and removing the substrate. The 2D thin film will bend or curl towards the layer (supportive layer or thin film layer) with higher coefficient of thermal expansion and form 3D tube-shaped structure.

### BRIEF DESCRIPTION OF THE DRAWINGS

The components, characteristics and advantages of the present invention may be understood by the detailed description of the preferred embodiments outlined in the specification and the drawings attached.

FIG. 1 illustrates a flow chart of preparing the patterned thin film with tethered 3D tube-shaped structure according to an embodiment of the present invention.

FIG. 2A illustrates a sectional view of the substrate, supportive layer and thin film layer according to an embodiment of the present invention.

FIG. 2B illustrates a sectional view of opening a concavity at a side of the supportive layer according to an embodiment of the present invention.

FIG. 2C illustrates a sectional view of rolled-up structure according to an embodiment of the present invention.

FIG. 3A illustrates a diagram of supportive layer without pattern according to an embodiment of the present invention.

FIG. 3B illustrates a diagram of the supportive layer with pattern according to an embodiment of the present invention.

FIG. 3C illustrates a diagram of concavities at three sides of the supportive layer according to an embodiment of the present invention.

FIG. 3D illustrates a diagram of tethered tube-shaped thin film according to an embodiment of the present invention.

FIG. 4 illustrates a flow chart of preparing the patterned thin film with untethered 3D tube-shaped structure according to an embodiment of the present invention.

FIG. 5A illustrates a sectional view of the substrate, supportive layer and thin film layer according to an embodiment of the present invention.

FIG. 5B illustrates a sectional view of opening a concavity at a side of the supportive layer according to an embodiment of the present invention.

FIG. 5C illustrates a sectional view of rolled-up structure according to an embodiment of the present invention.

FIG. 6A illustrates a diagram of supportive layer without pattern according to an embodiment of the present invention.

FIG. 6B illustrates a diagram of the supportive layer with pattern according to an embodiment of the present invention.

FIG. 6C illustrates a diagram of concavities at four sides of the supportive layer according to an embodiment of the present invention.

FIG. 6D illustrates a diagram of untethered tube-shaped thin film according to an embodiment of the present invention.

FIG. 7A illustrates a SEM image of the tethered thin film with 3D rolled-up structure.

FIG. 7B illustrates a SEM image of the untethered thin film with 3D rolled-up structure.

FIGS. 8A-8B illustrate SEM images of 3D rolled-up structure.

FIG. 9A illustrates a SEM image of 3D rolled-up structure with single turn.

FIG. 9B illustrates a SEM image of 3D rolled-up structure with double turns.

FIG. 9C illustrates a SEM image of 3D rolled-up structure with triple turns.

FIG. 10A illustrates a SEM image of 3D rolled-up structure with supportive layer.

FIG. 10B illustrates a SEM image of 3D rolled-up structure without supportive layer.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims. The layout of components may be more complicated in practice.

### First Preferred Embodiment

### Tethered 3D Thin Film

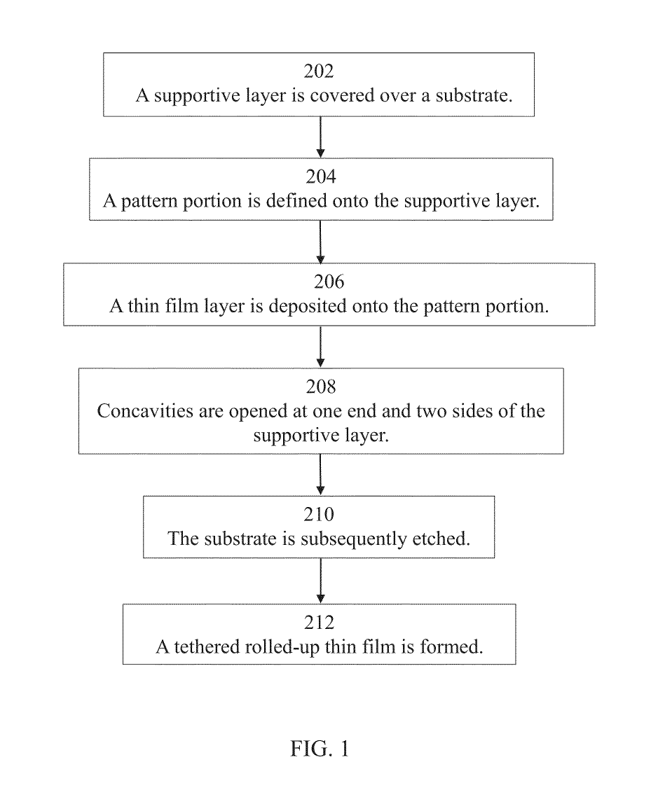

FIG. 1 illustrate a flow chart of preparing a patterned thin film with tethered rolled-up hollow structure according to an embodiment of the present invention. The method provides at least one substrate, such as silicon material, for following steps:

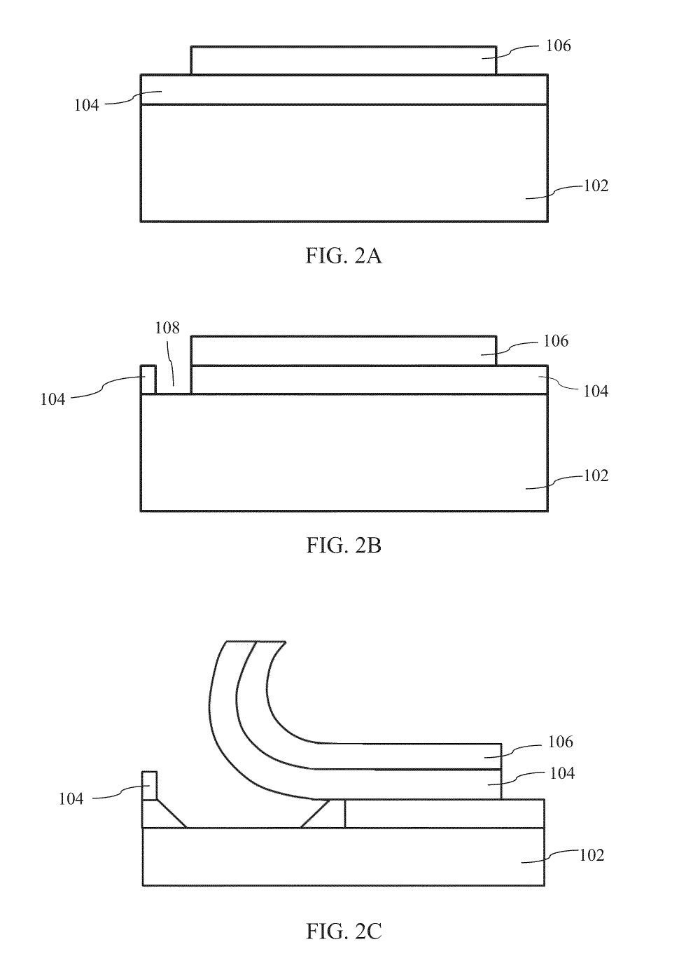

Step 202: A supportive layer 104 is covered over the substrate 102. FIG. 2A illustrates a sectional view of the substrate 102, a supportive layer 104 and a thin film layer 106 of the present invention. The supportive layer 104 includes, but is not limited to SiO₂ or Si₃N₄, in the preferred embodiment, the supportive layer 104 is SiO₂. The supportive layer 104 is formed over the substrate 102 by coating, printing or other process. In the preferred embodiment, the supportive layer 104 is covered over the substrate 102 by coating. The thickness of the supportive layer 104 is can be about 10-100 nm, more particularly, about 100 nm.

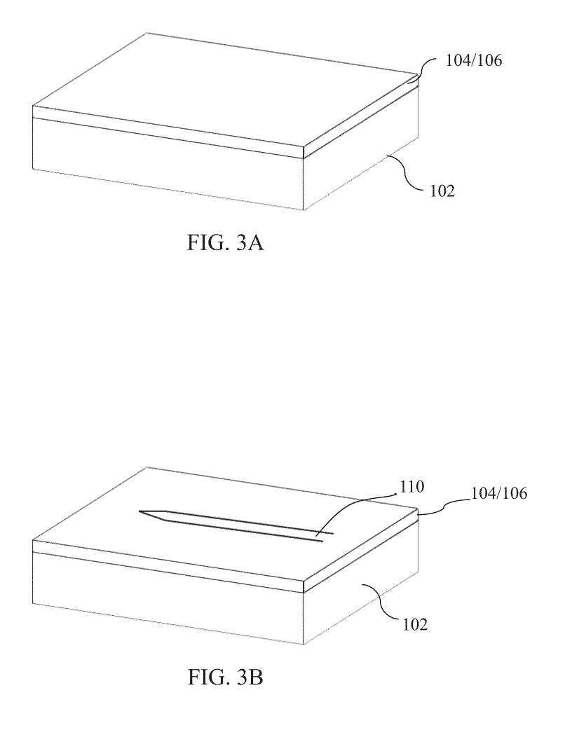

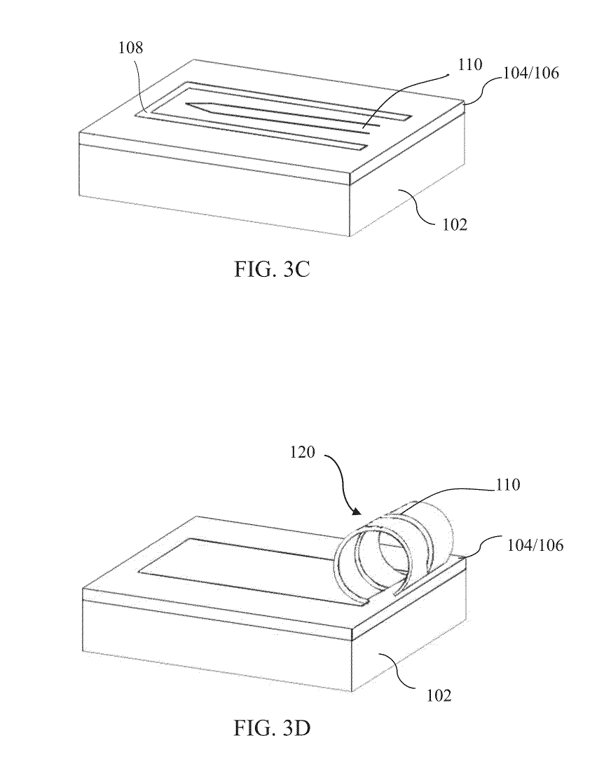

Step 204: A micro-pattern is defined on the supportive layer 104. FIGS. 3A-3B illustrate processes of patterning portion 110 formed on the supportive layer 104. It should be noted that the supportive layer 104 and the thin film layer 106 are combined into a single layer in order to simplify references in drawings. It is well understood that the present invention must coat a photoresist agent on the surface of the supportive layer 104 in order to define a pattern. Either positive resist or negative resist can be adapted for defining patterns based on the specific requirements. In the preferred embodiment, a positive resist polymethylmethacrylate (PMMA) is covered on the supportive layer 104 by spin coating, and then continues following steps.

Step 206: A thin film layer 106 is deposited onto the pattern portion 110. A required material can be coated onto the supportive layer 104, such as but not limited to magnetic material, conductive/non-conductive material or semiconductive material, after defining the pattern portion 110. In one embodiment, the thin film layer 106, coated onto the surface of the supportive layer 104 includes, but is not limited to Nickel-Iron (Ni₈₀Fe₂₀) alloy. In the preferred embodiment, the thin film layer 106 is deposited onto the surface of the supportive layer 104 by e-beam evaporation. In the preferred embodiment, the thin film layer 106 includes, but is not limited to Cr and Ni₈₀Fe₂₀ (not shown in drawings). We used the e-beam evaporation system to deposit (1) about 5-20 nm thick Cr as the adhesive layer, preferable 10 nm; (2) a layer of Ni₈₀Fe₂₀ ranges from 30 nm to several micrometers as the sensing layer, preferable 90 nm; and (3) about 5-20 nm thick Cr as the protective layer, preferable 10 nm, in sequence. Accordantly, 2D patterned thin film with will be done through above steps.

Step 208: A concavity 108 is opened on at least one side of the supportive layer 104. In an embodiment, a concavity 108 is formed at the front (or back), right and left sides, respectively, of the pattern portion 110 of the supportive layer 104. FIG. 2B illustrates a sectional view of the concavity 108 formed at one sides of the supportive layer 104. FIG. 3C illustrates a perspective view of the concavity 108 formed at three sides of the supportive layer 104. First of all, the shape of required concavities are defined onto the supportive layer 104 and the thin film layer 106 by lithography, and then the concavities are etched by buffered oxide etchant (BOE). As shown in FIG. 3C, each of left, right and front (or back) side of the supportive layer 104 and the thin film layer 106 has its concavity, respectively, to assist 2D thin film form rolled-up structure 120 (also called tube-shaped or ring-shaped structure or tubular structure). It is well understood that the height and width of concavities 108 can be modified or varied based on requirements by the skilled person in the art.

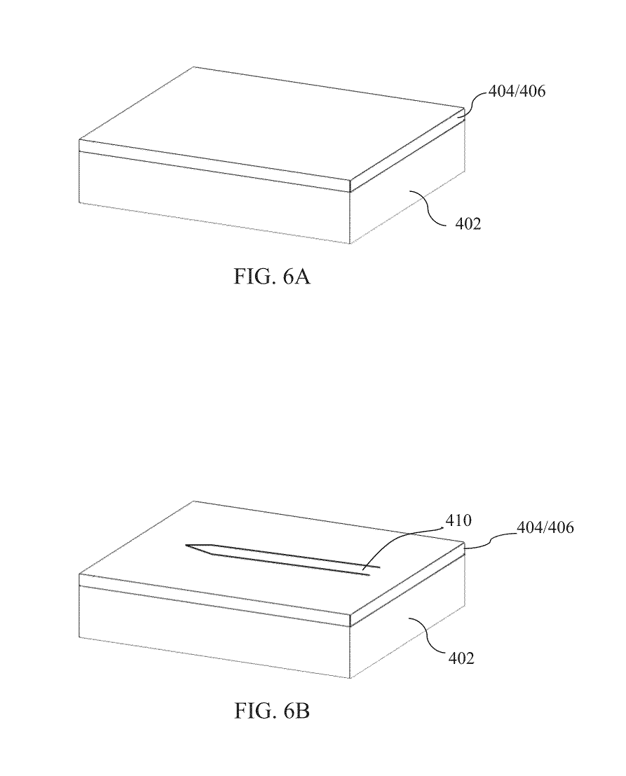

FIG. 7A illustrates a SEM image of tetherable thin film with tube-shaped structure, that is tethered at a side of the substrate. The width of the concavity 108 is 5 micrometers. The width and diameter of the tube-shaped structure are 8 and 19 micrometers, respectively.

Step 210: The substrate 102 is subsequently etched. The substrate 102, after step 208, is immersed into etchant, such as tetramethylammonium hydroxide (TMAH) for removing parts of the substrate 102 to form the tube-shaped structure 120. Referring to FIG. 2C, the supportive layer 104 and the thin film layer 106 bend or curl towards a side of the substrate 102 to form the tube-shaped structure 120 in etching process is due to the difference in thermal expansion coefficient between the supportive layer 104 and the depositing material 106. In the embodiment, the etchant includes, but is not limited to TMAH (N(CH₃)₄⁺OH⁻).

Step 212: The thin film layer 106 and the supportive layer 104 can roll up due to stress induced by the difference in thermal expansion between different layers are released after substrate etching, and a tethered thin film with 3D structure 120 is created. If the thermal expansion coefficient of the supportive layer 104 is greater than that of the thin film layer 106, they will bent towards a side of the supportive layer 104 (away from a side of the thin film layer 106), thereby rolling downward (not shown in FIG.) If the thermal expansion coefficient of the supportive layer 104 is smaller than the thin film layer 106, they will bent towards a side of the thin film layer 106 (away from a side of the supportive layer 104), thereby rolling upward and forming the tube-shaped structure 120, as shown in FIGS. 2C and 3D. In the preferred embodiment, the thermal expansion coefficient of Cr, Ni₈₀Fe₂₀ and SiO₂ are 6.2 (10⁻⁶/mK), 12.8 (10⁻⁶/mK) and 0.5 (10⁻⁶/mK), respectively, so the supportive layer 104 will bent towards a side of Ni₈₀Fe₂₀. The difference of thermal expansion coefficient between the depositing 106 and the supportive layer 104 is about 4.8-12.3 (10⁻⁶/mK).

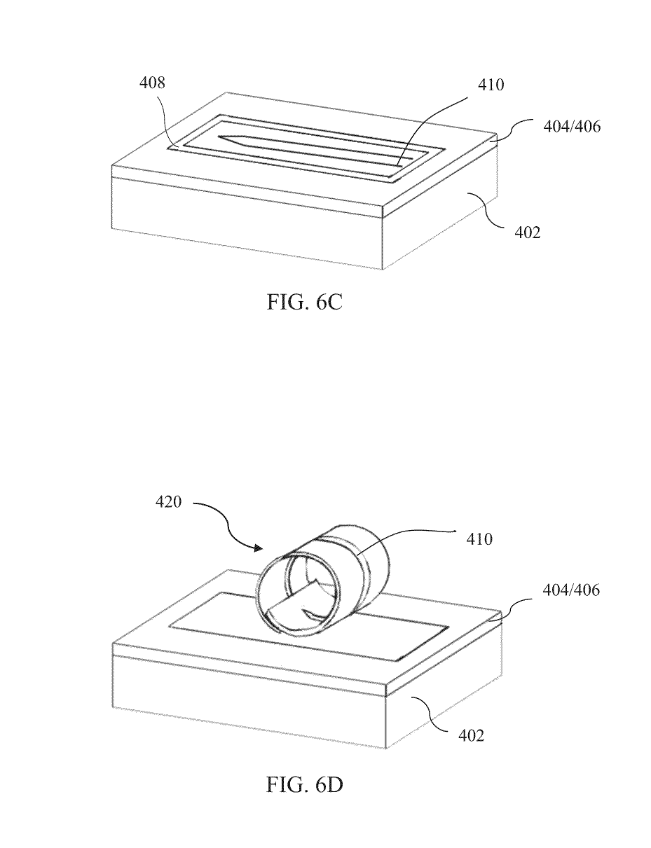

In another embodiment, various length of the tube-shaped thin film can be formed by modulating the distance between left and right sides, as shown in FIGS. 8A and 8B, they illustrate SEM images of tube-shaped thin film with lengths of 8 and 140 micrometers.

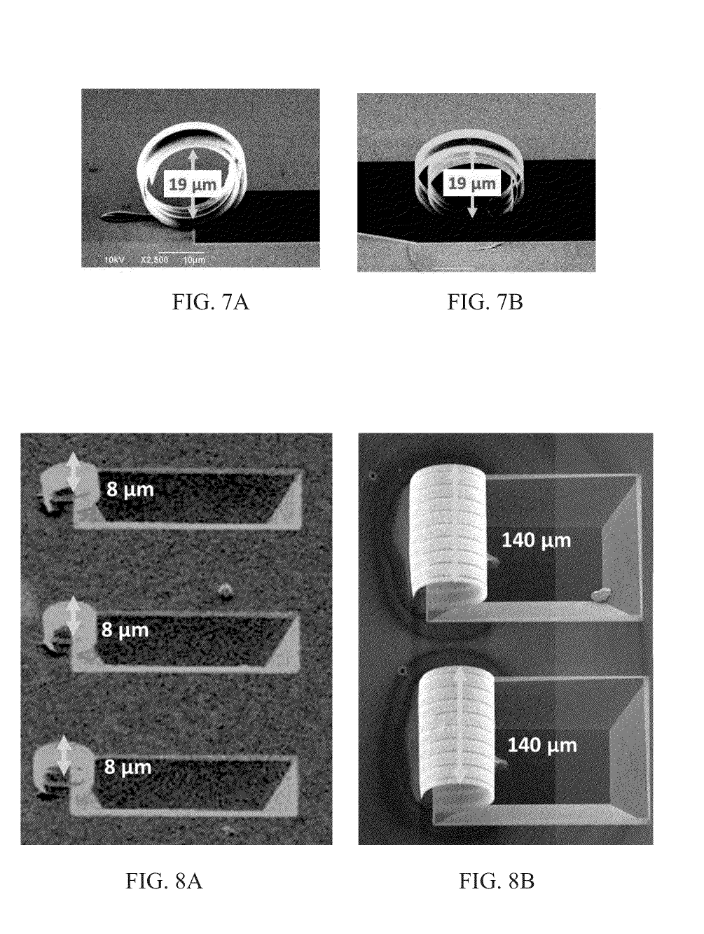

The present invention also provides a fabrication of tube-shaped thin film with single turn and multiple turns by modulating the thickness of the supportive layer 104, the etching temperature and the distance between the front and the back concavities 108. FIGS. 9A-9C, they illustrate tube-shaped thin film with single turn, double turns and triple turns, respectively. In above embodiment, the thickness of the thin film 104 is 100 nanometers, and diameter of tube-shaped thin film with single turn, double turns and triple turns are 15, 17, 19 micrometers, respectively, by modulating the length of front concavity to back concavity. It is well understood that the diameter raises as the number of turns increased.

On the other hand, diameter and turns can be modulated by external factors, such as etching time and temperature. In one embodiment, etching rate rises as temperature from 60° C. to 150° C., and thus the number of turns (N) of the tube-shaped structure 120 will be made. In one embodiment, the number of turns (N) is 3 under temperature between 90° C.-110° C.; in contrary, the number of turns (N) is 1 under temperature between 60° C.-80° C. Accordantly, the number of turns (N) are proportional to the temperature. It is well understood that the desired operating temperature is based on the depositing material chosen in thin film layer.

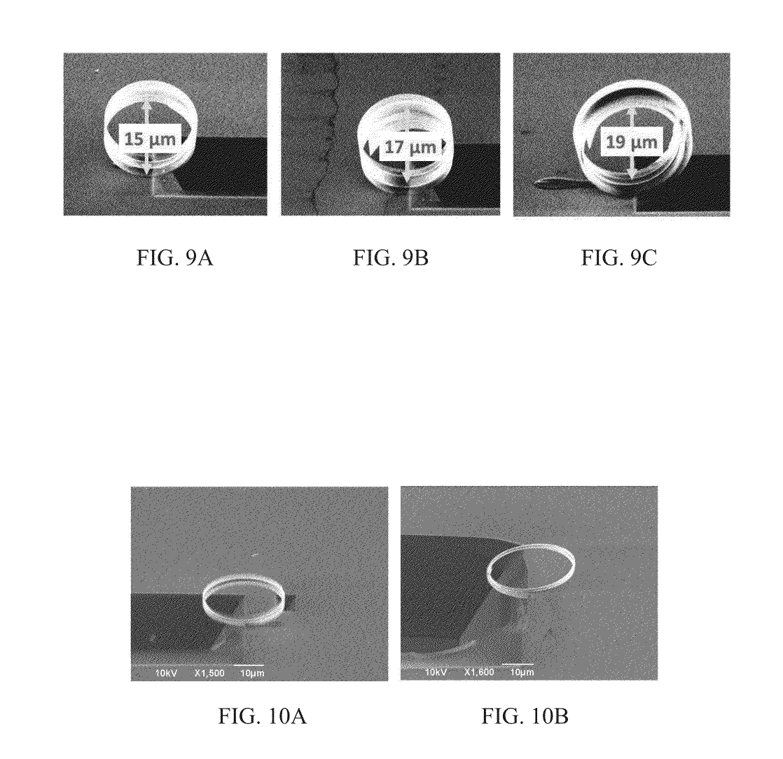

In an embodiment, removing the supportive layer 104 of the tube-shaped thin film can reduce the inference problem during sensing/detecting. As shown in FIGS. 10A and 10B, they illustrate the tube-shaped structure prior to and posterior to removing the supportive layer 104, respectively.

### Second Preferred Embodiment

### Untethered 3D Thin Film

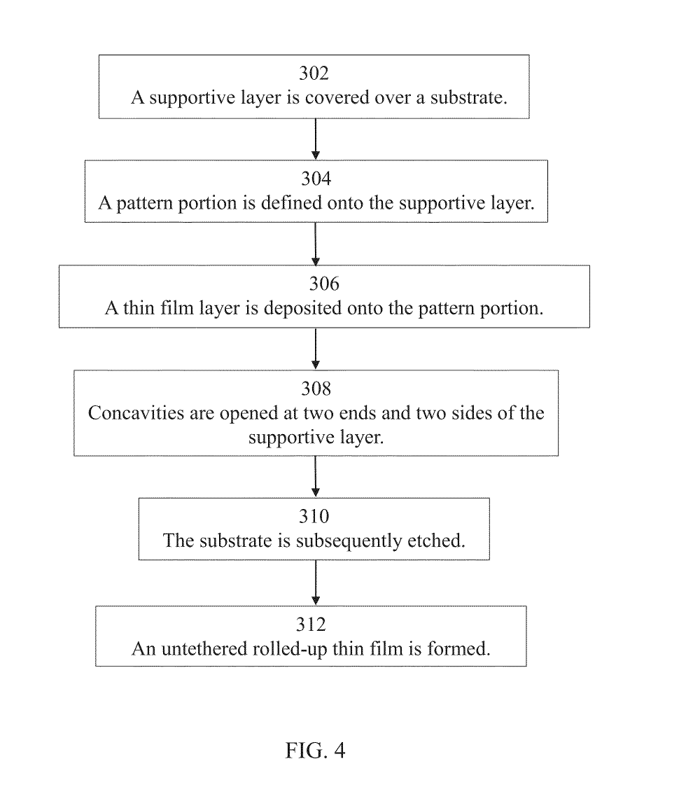

Step 302: A supportive layer 404 is covered over the substrate 402. FIG. 5A illustrates a sectional view of the substrate 402, a supportive layer 404 and a thin film layer 406 of the present invention. The supportive layer 404 includes, but is not limited to SiO₂ or Si₃N₄, in the preferred embodiment, the supportive layer 404 is SiO₂. The supportive layer 404 is formed over the substrate 402 by coating, printing or other process. In the preferred embodiment, the supportive layer 404 is covered over the substrate 402 by coating. The thickness of the supportive layer 404 is can be about 10-100 nm, more particularly, about 100 nm.

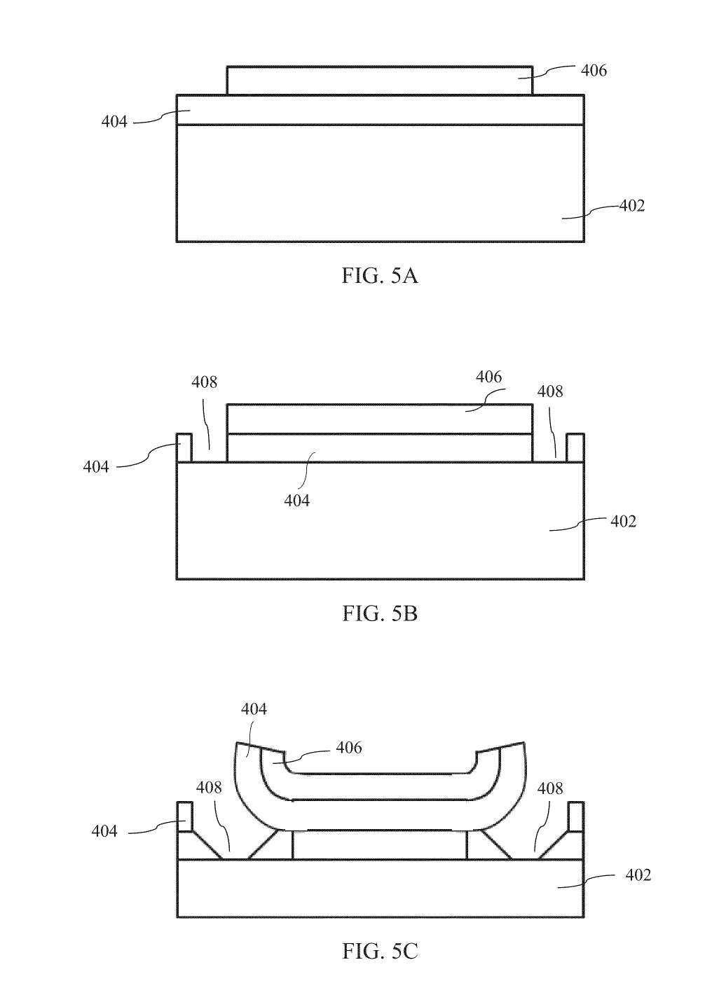

Step 304: A micro-pattern is defined on the supportive layer 404. FIGS. 6A-6B illustrate processes of patterning portion 410 formed on the supportive layer 404. It should be noted that the supportive layer 404 and the thin film layer 406 are combined into a layer in order to simplify references in drawings. It is well understood that the present invention must coat a photoresist agent on the surface of the supportive layer 404 in order to define a pattern. Either positive resist or negative resist can be adapted for defining patterns based on the specific requirements. In the preferred embodiment, a positive resist polymethylmethacrylate (PMMA) is covered on the supportive layer 404 by spin coating, and then continues following steps. In the preferred embodiment, the pattern portion 410 are created onto the substrate 402 that spin-coated with e-beam resist polymethyl methacrylate (PMMA). Then, the pattern portion 410 will be appeared on the substrate 402 in developer, such as 3:1 mixture of 2-propanol and methyl isobutyl ketone. It is well understood that the lithographic technique is not limited to e-beam lithography, but can be varied or modified by the person in the art in the light of the need in use. Besides, in step 404, the fabrication further includes dehydration baking, priming, soft baking and hard baking to enhance precision and reliability of the pattern portion 410.

Step 306: A thin film layer 406 is deposited onto the pattern portion 410. A required material can be coated onto the supportive layer 404, such as but not limited to magnetic material, conductive material, non-conductive material or semiconductive material, after defining the pattern portion. In one embodiment, the thin film layer 406, coated onto the surface of the supportive layer 404, includes, but is not limited to Fe-Ni alloy. In the preferred embodiment, the thin film layer 406 is depositing onto the surface of the supportive layer 404 by e-beam evaporation. In the preferred embodiment, the thin film layer 406 includes, but is not limited to Cr and Ni₈₀Fe₂₀ (not shown in drawings). We used the e-beam evaporation system to deposit (1) about 5-20 nm thick Cr as the adhesive layer, preferable 10 nm; (2) a layer of Ni₈₀Fe₂₀ ranges from 30 nm to several micrometers as the sensing layer, preferable 90 nm; and (3) about 5-20 nm thick Cr as the protective layer, preferable 10 nm, in sequence. Accordantly, patterned thin film with 2D planar will be done through above steps.

Step 308: A concavity 408 is opened on at least one side of the supportive layer 404. In an embodiment, a concavity 408 is formed at the front, back, right and left sides, respectively, of the pattern portion 410 of the supportive layer. FIG. 5C illustrates a sectional view of the concavity 408 formed at a side of the supportive layer 404. FIG. 6C illustrates a perspective view of the concavity 408 formed at four sides of the supportive layer 404. First, the shape of required concavities are defined onto the supportive layer 404 and the thin film layer 406 by lithography, then the concavities are etched by buffered oxide etchant (BOE). As shown in FIG. 6C, each of left, right, front, and back sides of the supportive layer 404 and the thin film layer 106 has its concavity, respectively, for forming rolled-up thin film 420 (also called tube-shaped or ring-shaped structure or tubular structure). It is well understood that the height and width of concavities 408 can be modified or varied based on requirements by the skilled person in the art.

FIG. 7B illustrates a SEM image of untetherable thin film with tube-shaped structure, that is tethered at a side of the substrate. The width of the concavity 408 is 5 micrometers. The width and diameter of the tube-shaped thin film are 8 and 19 micrometers, respectively.

Step 310: Etching the substrate 402. The substrate 402, after step 308, is immersed into etchant, such as tetramethylammonium hydroxide (TMAH) for removing parts of the substrate 402 to form the tube-shaped thin film 420. Referring to FIG. 5C, the supportive layer 404 and the thin film layer 406 bend or curl towards a side of the substrate 402 to form the tube-shaped structure 420 in etching process, due to the difference in thermal expansion coefficient between the supportive layer 404 and the thin film layer 406. In the embodiment, the etchant includes, but is not limited to TMAH (N(CH₃)₄⁺OH⁻).

Step 312: The thin film layer 406 and the supportive layer 404 can roll up owing to stress induced by the difference in thermal expansion between different layers are released after substrate etching, and then an untethered thin film with 3D structure 420 is created. If the thermal expansion coefficient of the supportive layer 404 is greater than that of the thin film layer 406, they will bent towards a side of the supportive layer 404 (away from a side of the thin film layer 406), thereby rolling downward (not shown in FIG.) If the thermal expansion coefficient of the supportive layer 404 is smaller than the thin film layer 406, they will bent towards a side of the thin film layer 406 (away from a side of the supportive layer 404), thereby rolling upward and forming the tube-shaped thin film 420, as shown in FIGS. 5C and 6D. In the preferred embodiment, the thermal expansion coefficient of Cr, Ni₈₀Fe₂₀ and SiO₂ are 6.2 (10⁻⁶/mK), 12.8(10⁻⁶/mK) and 0.5(10⁻⁶/mK), respectively, so the supportive layer 404 will bent towards a side of Ni₈₀Fe₂₀. The difference of thermal expansion coefficient between the thin film layer 106 and the supportive layer 104 is about 4.8-12.3 (10⁻⁶/mK).

On the other hand, diameter and turns can be modulated by external factors, such as etching time and temperature. In one embodiment, etching rate rises as temperature from 60° C. to 150° C., and thus the number of turns (N) of the tube-shaped structure 120 will be made. In one embodiment, the number of turns (N) is 3 under temperature between 90° C.-110° C.; in contrary, the number of turns (N) is 1 under temperature between 60° C.-80° C. Accordantly, the number of turns (N) are proportional to the temperature. It is well understood that the desired operating temperature is based on the depositing material chosen in thin film layer.

In the texture, the terms “one end”, “one side”, “two ends” and “two sides” refer to any one side (or end) of the pattern portion. In order to distinguish and clarity, “two ends” and “one end” refer to the front end and/or back end corresponding thereof, for example in FIGS. 3A-3D, “front end” and “back end” refer to the left side and right side in drawings, respectively. “Two sides” and “one side” refer to the left side and/or right side corresponding thereof, for example, in FIGS. 3A-3D, “left side” and “right side” refer to the bottom side and top side in drawings, respectively. The term “side” is changeable with “end”, not limited to above embodiment. The difference between tube-shaped and ring-shaped is only length of the specification, theoretically, the length of the tube-shaped is longer than that of the ring-shaped.

As description above, the present invention provides fabrication of a patterned thin film with 3D rolled-up structure. The 3D rolled-up thin film can be serve as biosensor to dissolve disadvantage of conventional 2D sensor. In addition, the 3D rolled-up thin film also increase the amount of collected cells and detective direction as a result of its rolled-up structure which can enhance the signal.

Various terms used in this disclosure should be construed broadly. For example, if an element “A” is said to be coupled to or with element “B,” element A may be directly coupled to element B or be indirectly coupled through, for example, element C. When the specification states that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification refers to “a” or “an” element, this does not mean there is only one of the described elements.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A fabrication of a tetherable patterned thin film with 3D tube-shaped structure, comprising:
preparing a substrate;
covering a supportive layer onto said substrate;
defining a pattern portion onto said supportive layer;
depositing a thin film layer onto said pattern portion;
opening at least one concavity onto said supportive layer;
removing said substrate in a temperature range; and
forming a tube-shaped thin film.

2. The fabrication of claim 1, wherein said concavity formed at an end and two sides of said pattern portion respectively to form a tethered tube-shaped thin film.

3. The fabrication of claim 1, wherein said concavity formed two ends and two sides of said pattern portion respectively to form an untethered tube-shaped thin film.

4. The fabrication of claim 1, wherein said pattern portion is defined onto a photoresist of said thin film by lithography, and said substrate is removed by etching.

5. The fabrication of claim 1, wherein said thin film layer comprises magnetic material, conductive material, non-conductive material and semiconducitve material.

6. The fabrication of claim 1, wherein a difference of thermal expansion coefficient between said supportive layer and said thin film layer is 4.7-12.3 (10⁻⁶/mK), wherein said temperature range is 60° C.-150° C.

7. The fabrication of claim 1, wherein a thermal expansion coefficient of said thin film layer is greater than that of said supportive layer, so as to bend towards a side of said thin film layer to roll upwards to away from said substrate.

8. The fabrication of claim 1, wherein a thermal expansion coefficient of said thin film layer is smaller than that of said supportive layer, so as to bend towards a side of said supportive layer to roll downwards.

9. The fabrication of claim 1, wherein said tube-shaped thin film comprises at least one turn by modulating the distance between a front concavity to a back concavity, etching time and temperature.

10. The fabrication of claim 1, wherein said tube-shaped thin film with variety of length can be formed by modulating the distance between a left concavity to a right concavity.
